(19) United States
(12) Patent Application Publication
(10) Pub. No.: US 2026/0366945 A1
(43) Pub. Date: Nov. 19, 2026

(54) Battery Pack, Battery Apparatus and Method for Detecting Electrolyte Leakage

(71) Applicant: LG Energy Solution, Ltd., Seoul (KR)

(72) Inventor: Dong Hyeon Kim, Daejeon (KR)

(73) Assignee: LG Energy Solution, Ltd., Seoul (KR)

(21) Appl. No.: 19/121,861

(22) PCT Filed: Aug. 16, 2023
(86) PCT No.: PCT/KR2023/012071

§ 371 Date: Apr. 17, 2025

(30) Foreign Application Priority Data
Dec. 23, 2022 (KR) 10-2022-0183570

(51) Int. Cl. G01M 3/16; G01R 19/00; G01R 19/165; H01M 10/42; H01M 10/48

(52) U.S. Cl. CPC G01M 3/16; G01R 19/0038; G01R 19/16576; H01M 10/4228; H01M 10/48

(57) ABSTRACT

A battery pack may include a battery module that includes a plurality of battery cells, a battery monitoring circuit configured to monitor the battery module, and an electrolyte solution leakage detection sensor configured to detect an electrolyte solution leakage in the battery module, and the electrolyte solution leakage detection sensor may include a first resistor and an electrolyte solution detection circuit that are connected in series between a power source for supplying a first voltage and a ground terminal, a second resistor and a third resistor that are connected in series between the power source and the ground terminal, and a comparison circuit.

### CROSS-REFERENCE TO RELATED APPLICATION

The present application is a national phase entry under 35 U.S.C. § 371 of International Application No. PCT/KR 2023/012071 filed Aug. 16, 2023, which claims priority from Korean Patent Application No. 10-2022-0183570 filed in the Korean Intellectual Property Office on Dec. 23, 2022, the entire contents of which are incorporated herein by reference.

### TECHNICAL FIELD

The present disclosure relates to a battery pack, a battery device, and an electrolyte solution leakage detection method.

### BACKGROUND

Electric vehicles and hybrid vehicles are vehicles obtaining power by mainly using batteries as power sources for driving motors, and are alternatives capable of solving pollution and energy problems of internal combustion vehicles. For this reason, research has been actively carried out on them. Further, rechargeable batteries have been used in various other external apparatuses, as well as in vehicles.

Batteries are provided in the form of a battery pack including battery modules, in each of which a plurality of battery cells is connected. The lower cases of battery packs have structures to be connected to external devices, for example, the chassis of vehicles. In this case, if an electrolyte solution leaks from a battery cell of a battery pack, the leaked electrolyte solution may create a path between the battery cell and the lower case of the battery pack, which may break down the insulation. This insulation breakdown may result in a fire in the battery pack or damage to components using low voltages in the vehicle. For this reason, it is required to detect leakage of an electrolyte solution in a battery pack.

### SUMMARY

### Technical Problem

The present disclosure attempts to provide a battery pack, a battery device, and an electrolyte solution leakage detection method capable of detecting leakage of an electrolyte solution in a battery pack.

### Technical Solution

A battery pack according to an exemplary embodiment may include a battery module that includes a plurality of battery cells, a battery monitoring circuit connected to the battery module and configured to monitor the battery module, and an electrolyte solution leakage detection sensor configured to detect an electrolyte solution leakage in the battery module, and the electrolyte solution leakage detection sensor may include a first resistor and an electrolyte solution detection circuit that are connected in series between a power source for supplying a first voltage and a ground terminal, a second resistor and a third resistor that are connected in series between the power source and the ground terminal, and a comparison circuit configured to receive a detection voltage of a contact point of the first resistor and the electrolyte solution detection circuit as a first input voltage, and receive a voltage of a contact point of the second resistor and the third resistor as a second input voltage, and transmit an output voltage to an input terminal of the battery monitoring circuit.

In some exemplary embodiments, the comparison circuit may be configured to output a high-level voltage signal when the first input voltage is smaller than the second input voltage, and output a low-level voltage signal when the first input voltage is larger than the second input voltage.

In some exemplary embodiments, the electrolyte solution leakage detection sensor may be configured to diagnose the electrolyte solution leakage when the output voltage is higher than a reference voltage.

In some exemplary embodiments, the electrolyte solution detection circuit may include a first detection node and a second detection node, and when the first detection node and the second detection node are electrically connected, the electrolyte solution leakage detection sensor may be configured to diagnose the electrolyte solution leakage. In some exemplary embodiments, the battery pack may further include an RC filter circuit configured to receive the detection voltage of the contact point of the first resistor and the electrolyte solution detection circuit and transfer the detection voltage to the comparison circuit.

In some exemplary embodiments, the battery pack may further include a voltage regulator configured to generate the first voltage from a voltage of the battery module. In some exemplary embodiments, the battery pack may further include a lower case of the battery pack, and a lower cover formed on the lower case, and below the battery module, configured to collect the electrolyte solution which leaks in the battery module, and the electrolyte solution leakage detection sensor is attached to the lower cover.

In some exemplary embodiments, the battery monitoring circuit may be configured to monitor the battery module in an active mode of the battery monitoring circuit.

In some exemplary embodiments, the battery pack may further include a pulse generator configured to generate a pulse signal for switching the battery monitoring circuit to the active mode and output the pulse signal to an output terminal, when the output voltage is higher than a threshold voltage, and a transfer circuit configured to transfer the pulse signal to a transmission terminal of the battery monitoring circuit in a shutdown mode, and blocks a transfer of the pulse signal to the transmission terminal of the battery monitoring circuit in the active mode.

A battery device according to an exemplary embodiment may include a battery module that includes a plurality of battery cells, a battery monitoring circuit connected to the battery module and configured to monitor the battery module, an electrolyte solution leakage detection sensor configured to detect an electrolyte solution leakage in the battery module, and a battery management system configured to manage the battery monitoring circuit and diagnose the electrolyte solution leakage based on information received from the battery monitoring circuit, and the electrolyte solution leakage detection circuit may have resistance value that varies in response to the electrolyte solution leakage in the battery module, and transmit an output voltage of a comparison circuit, which is determined based on a resistance value of the electrolyte solution detection unit, to an input terminal of the battery monitoring circuit.

In some exemplary embodiments, the battery management system may be configured to diagnose the electrolyte solution leakage in the battery module in response to the output voltage being higher than a reference voltage based on information transmitted from the battery monitoring circuit.

In some exemplary embodiments, the electrolyte solution leakage detection sensor may include a first resistor and the electrolyte solution detection circuit that are connected in series between a power source for supplying a first voltage and a ground terminal, a second resistor and a third resistor that are connected in series between the power source and the ground terminal, and a comparison circuit configured to receive a detection voltage of the contact point of the first resistor and the electrolyte solution detection circuit as a first input voltage, and receive a voltage of the contact point of the second resistor and the third resistor as a second input voltage, and transmits an output voltage to an input terminal of the battery monitoring circuit.

In some exemplary embodiments, the battery device may further include a pulse generator configured to transmit a pulse signal to a transmission terminal of the battery monitoring circuit when the electrolyte solution leakage detection sensor detects the electrolyte solution leakage in the battery module in a shutdown mode of the battery monitoring circuit, and the battery monitoring circuit may be configured to transition the battery module to an active mode in response to the pulse signal.

In some exemplary embodiments, the pulse generator may be configured to generate the pulse signal in response to the output voltage being higher than a threshold voltage.

In some exemplary embodiments, the battery device may further include a transistor connected between an output terminal of the pulse generator and a ground terminal, and controls a transfer of the pulse signal to a transmission terminal of the battery monitoring circuit based on a voltage supplied to a power terminal of the battery monitoring circuit.

In some exemplary embodiments, the battery module may be in the active mode, in response to a second voltage being supplied to the power terminal of the battery monitoring circuit, and the battery module may be in the shutdown mode, in response to the second voltage being blocked so as not to be supplied to the power terminal of the battery monitoring circuit, and the transistor may be turned on to block a transfer of the pulse signal in response to the second voltage in the active mode, and be turned off to transfer the pulse signal in response to the blocking of the second voltage in the shutdown mode.

In some exemplary embodiments, the battery device may further include a lower cover, which is formed below the battery module, configured to collect the electrolyte solution leakage in the battery module, and has the electrolyte solution leakage detection sensor attached thereto.

An electrolyte solution leakage detection method according to an exemplary embodiment is an electrolyte solution leakage detection method of a battery device which includes a battery module, a battery monitoring circuit for monitoring the battery module, and an electrolyte solution leakage detection sensor, and may include generating a pulse signal when an electrolyte solution leaks in the battery module in a state where the battery monitoring circuit is in a shutdown mode, switching the battery monitoring circuit to an active mode in response to the pulse signal, allowing the electrolyte solution leakage detection sensor to measure an output voltage based on a resistance value which varies in response to the electrolyte solution leakage, and commanding the battery monitoring circuit, in the active mode, to diagnose the electrolyte solution leakage in response to the output voltage being higher than a reference voltage.

In some exemplary embodiments, the method further comprises receiving a detection voltage of the contact point of a first resistor and the electrolyte solution detection circuit as a first input voltage, receiving a voltage of the contact point of a second resistor and a third resistor as a second input voltage, and comparing the first input voltage and the second input voltage, outputting a high-level voltage signal when the first input voltage is smaller than the second input voltage, and outputting a low-level voltage signal when the first input voltage is larger than the second input voltage.

### Advantageous Effects

According to the exemplary embodiments, since electrolyte solution leakage detection is noise-robust, it is possible to prevent the electrolyte solution leakage detection sensor from being short-circuited while preventing malfunctions, and it is possible to protect the battery module, the electrolyte solution leakage detection sensor, and the battery monitoring circuit by limiting current.

### BRIEF DESCRIPTION OF THE DRAWINGS

FIG. 1 is a drawing illustrating a battery device according to an exemplary embodiment.

FIGS. 2 and 3 are drawings illustrating an electrolyte solution leakage detection device according to an exemplary embodiment.

FIGS. 4 and 5 are drawings illustrating the operation of the electrolyte solution leakage detection device according to the exemplary embodiment.

FIG. 6 is a drawing illustrating an electrolyte solution leakage detection device according to an exemplary embodiment.

FIG. 7 is a flow chart illustrating an electrolyte solution leakage detection method of the battery device according to the exemplary embodiment.

FIG. 8 is a drawing illustrating an example of the structure of a battery pack according to an exemplary embodiment.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

It should be understood that when a constituent element is referred to as being “connected” to another constituent element, it may be directly connected to the other constituent element, or other constituent elements may be present between them. In contrast, it should be understood that when a constituent element is referred to as being “directly connected” to another constituent element, there is no other constituent element between them.

In the following description, expressions written in the singular forms can be comprehended as the singular forms or plural forms unless clear expressions such as “a”, “an”, or “single” are used.

In the flow charts described with reference to the drawings, the order of operations may be changed, and several operations may be combined, and an operation may be divided, and some operations may not be performed.

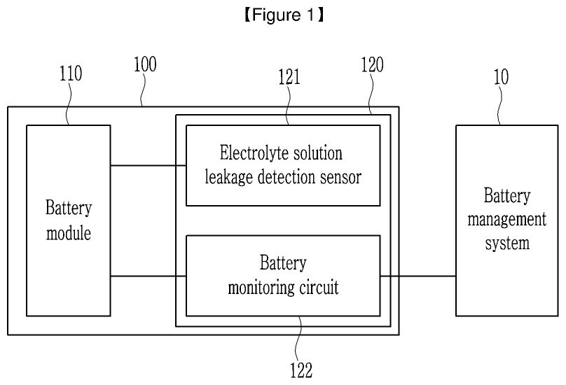

FIG. 1 is a drawing illustrating a battery device according to an exemplary embodiment.

Referring to FIG. 1, a battery device may include a battery pack 100 and a battery management system 10. The battery pack 100 may include a battery module 110 and an electrolyte solution leakage detection circuit 120.

The battery module 110 may include a plurality of battery cells (not shown in the drawings). In the exemplary embodiment, the battery cells may be rechargeable batteries, and these battery cells may include anodes, cathodes, and an electrolyte solution. In the exemplary embodiment, a predetermined number of battery cells may be connected in series or in parallel to constitute the battery module. In FIG. 1, one battery module 110 is shown for ease of explanation; however, the battery pack 100 may include one or more battery modules 110 to provide desired power.

The electrolyte solution leakage detection circuit 120 may include an electrolyte solution leakage detection sensor 121 and a battery monitoring circuit 122.

The electrolyte solution leakage detection sensor 121 may be connected to the battery module 110, and may detect leakage of the electrolyte solution from the battery cells included in the battery module 110 and transmit a signal to the battery monitoring circuit 122 when detecting leakage of the electrolyte solution.

The battery monitoring circuit 122 may be connected to the battery module 110 and monitor the voltages of the battery cells. In the exemplary embodiment, the battery monitoring circuit 122 may also measure the temperature of the battery module 110. In the exemplary embodiment, the battery monitoring circuit 122 may be provided in the form of an integrated circuit (IC). When the battery monitoring circuit 122 receives the signal from the electrolyte solution leakage detection sensor 121, it may transmit the corresponding information to an external device (for example, a vehicle).

The battery monitoring circuit 122 may perform communication with the battery management system 10 of the battery device. The battery management system 10 may control the operation of the battery pack 100 by collecting data (information) which are transmitted from the battery monitoring circuit 122. Also, the battery management system 10 may transmit the information collected from the battery monitoring circuit 122 to the external device (for example, the vehicle).

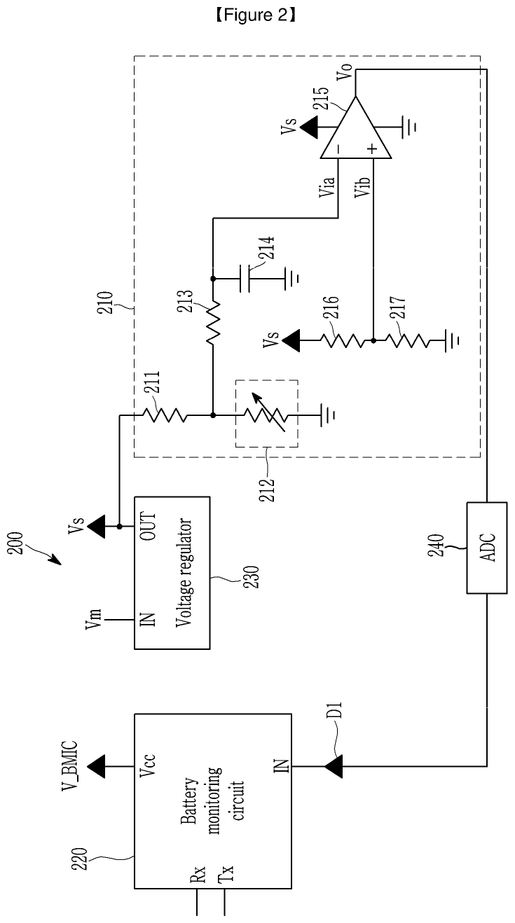

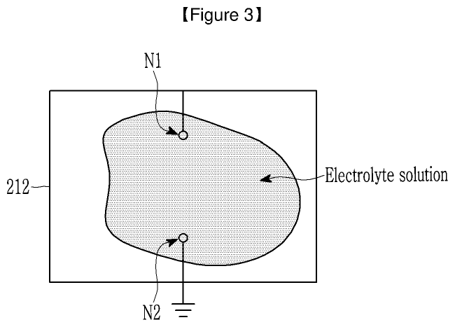

FIGS. 2 and 3 are drawings illustrating an electrolyte solution leakage detection device according to an exemplary embodiment.

Referring to FIG. 2, an electrolyte solution leakage detection device 200 may include an electrolyte solution leakage detection sensor 210 and a battery monitoring circuit 220. In the exemplary embodiment, the electrolyte solution leakage detection device 200 may correspond to the electrolyte solution leakage detection circuit 120 of FIG. 1.

In the exemplary embodiment, a power source for supplying a predetermined voltage Vs may be generated from the voltage of a battery module (for example, reference symbol “110” in FIG. 1). To this end, the electrolyte solution leakage detection device 200 may further include a voltage regulator 230. The voltage regulator 230 may receive the voltage Vm of the battery module 110 through an input terminal IN and output the predetermined voltage Vs through an output terminal OUT. The voltage Vs may be, for example, 5 V.

The electrolyte solution leakage detection sensor 210 may include a resistor 211 and an electrolyte solution detection unit 212 which are connected in series between the power source for supplying the predetermined voltage Vs and a ground terminal. The voltage of the contact point of the resistor 211 and the electrolyte solution detection unit 212 may be transferred as a detection voltage to RC filter circuits 213 and 214. The detection voltage may pass through the RC filter circuits 213 and 214 and then be input as a first input voltage Via to a comparison circuit 215. Here, the comparison circuit 215 may be an operational amplifier, and the first input voltage Via may be a voltage which is applied to the negative input terminal of the operational amplifier. Meanwhile, the electrolyte solution leakage detection sensor 210 may further include a plurality of resistors 216 and 217 which is connected in series between the power source for supplying the predetermined voltage Vs and the ground terminal. The voltage of the contact point of the plurality of resistors 216 and 217 may be input as a second input voltage Vib to the comparison circuit 215. Here, the second input voltage Vib may be a voltage which is applied to the positive input terminal of the operational amplifier.

The second input voltage Vib may be a fixed voltage for making the operational amplifier operate as a voltage comparator. For example, the plurality of resistors 216 and 217 may be set to the same resistance value as each other, and the second input voltage Vib may be set to half the value of the voltage Vs. Accordingly, when the first input voltage Via that is applied to the negative input terminal of the operational amplifier has a value larger than the second input voltage Vib, the output voltage Vo of the operational amplifier may have a value corresponding to a low level. On the other hand, when the first input voltage Via that is applied to the negative input terminal of the operational amplifier has a value smaller than the second input voltage Vib, the output voltage Vo of the operational amplifier may have a value corresponding to a high level.

In the exemplary embodiment, when the voltage Vs is set to 5 V, the resistors 211, 213, 216, and 217 may be set to 170 kΩ, 10 kΩ, 43 kΩ, and 43 kΩ, respectively, and a capacitor 214 with 47 μF may be used.

The electrolyte solution detection unit 212 may not form any current path when the electrolyte solution does not leak from the battery cells, and may form a current path by the leaked electrolyte solution when the electrolyte solution leaks from the battery cells. Referring to FIG. 3 together, the electrolyte solution detection unit 212 may include two electrolyte solution detection nodes N1 and N2 formed apart from each other. When the electrolyte solution leaks from the battery cells, the first detection node N1 and the second detection node N2 may be electrically connected.

As shown in FIG. 3, when the electrolyte solution is positioned between the first detection node N1 and the second detection node N2, since the electrolyte solution acts as a resistor having a value similar to that of the resistor 211, when the resistor 211 has been set to 170 kΩ, the same effect as if a resistor with 170 kΩ is connected in series between the voltage Vs and the ground terminal may be caused. Accordingly, the detection voltage of the contact point of the resistor 211 and the electrolyte solution detection unit 212 may drop to a voltage value corresponding to half of the voltage Vs (2.5 V when the voltage Vs is 5 V), which may be applied as the first input voltage Via to the comparison circuit 215. At this time, the second input voltage Vib of the comparison circuit 215 may be the voltage value corresponding to half of the voltage Vs (2.5 V when the voltage Vs is 5 V). Accordingly, the resistance value of the electrolyte solution gradually decreases over time, although initially 170 kΩ. Accordingly, the first input voltage Via becomes lower than the voltage value corresponding to half of the voltage Vs. As a result, the first input voltage Via which is applied to the negative input terminal has a value smaller than the second input voltage Vib which is applied to the positive input terminal. In this case, the output voltage Vo of the comparison circuit 215 may become a high level (for example, 5 V).

In contrast, when the electrolyte solution does not leak from the battery cells, since the first detection node N1 and the second detection node N2 are not electrically connected, the detection voltage of the contact point of the resistor 211 and the electrolyte solution detection unit 212 may become a voltage value corresponding to the voltage Vs (5 V when the voltage Vs is 5 V), and be applied as the first input voltage Via to the comparison circuit 215. At this time, the second input voltage Vib of the comparison circuit 215 has a voltage value corresponding to half of the voltage Vs (2.5 V when the voltage Vs is 5 V). Accordingly, the first input voltage Via which is applied to the negative input terminal has a value larger than the second input voltage Vib which is applied to the positive input terminal. As a result, the output voltage Vo of the comparison circuit 215 may become a low level (for example, 0 V).

The battery monitoring circuit 220 may receive a signal corresponding to the output voltage Vo of the electrolyte solution leakage detection sensor 210 through the input terminal IN (for example, an input pin). In the exemplary embodiment, the input terminal IN may be one of various input terminals which are provided to be used for the battery monitoring circuit 220 to receive monitoring results. In the exemplary embodiment, the electrolyte solution leakage detection device 200 may further include an analog-to-digital converter (ADC) 240 for converting the output voltage Vo of the electrolyte solution leakage detection sensor 210 into a digital signal which the battery monitoring circuit 220 can receive. In the exemplary embodiment, the electrolyte solution leakage detection device 200 may further include a diode D1 to block a current path in the opposite direction (i.e., a current path from the input terminal IN of the battery monitoring circuit 220 to the output terminal of the electrolyte solution leakage detection sensor 210). The anode of the diode D1 may be connected to the output terminal of the electrolyte solution leakage detection sensor 210, and the cathode thereof may be connected to the input terminal IN of the battery monitoring circuit 220.

The battery monitoring circuit 220 may be operated by a predetermined voltage V_BMIC which is applied to a power terminal Vcc (for example, a power pin). In the exemplary embodiment, the predetermined voltage V_BMIC may be the same voltage as the predetermined voltage Vs of the electrolyte solution leakage detection sensor 210. Also, the battery monitoring circuit 220 may perform communication with a battery management system (for example, reference symbol “10” in FIG. 1) through a transmission terminal Tx (for example, a transmission pin) and a reception terminal Rx (for example, a reception pin). The battery monitoring circuit 220 may transmit monitored data to the battery management system 10 through a communication line for transmission connected between the transmission terminal Tx and the battery management system 10, and receive a control signal from the battery management system 10 through a communication line for reception connected between the reception terminal Rx and the battery management system 10. In the exemplary embodiment, communication between the battery monitoring circuit 220 and the battery management system 10 may be universal asynchronous receiver/transmitter (UART) communication.

The battery monitoring circuit 220 may transmit information corresponding to the output voltage Vo of the electrolyte solution leakage detection sensor 210 received through the input terminal IN to, for example, the battery management system 10. As described above, when the electrolyte solution does not leak, the output voltage Vo of the electrolyte solution leakage detection sensor 210 is the low-level voltage (for example, 0 V). Accordingly, when the output voltage Vo of the electrolyte solution leakage detection sensor 210 is a voltage lower than a reference voltage, a processor of the external device (for example, the vehicle) or the battery management system 10 may determine that the electrolyte solution has not leaked.

In contrast, when the electrolyte solution leaks, the output voltage Vo of the electrolyte solution leakage detection sensor 210 is the high-level voltage (for example, 5 V). Accordingly, when the output voltage Vo of the electrolyte solution leakage detection sensor 210 is higher than the reference voltage, the processor of the external device or the battery management system 10 may determine that the electrolyte solution has leaked. As described above, the battery management system 10 or the external device may detect leakage of the electrolyte solution in the battery pack through the output signal of the battery monitoring circuit 220, and perform a protection operation. In the exemplary embodiment, when the output voltage Vo is higher than the reference voltage, the battery management system 10 may transmit a warning signal to the external device (for example, the vehicle). Accordingly, the driver of the vehicle may have the battery pack checked.

According to the present exemplary embodiment, since the resistor 211 is disposed between the power source and the ground terminal, it is possible to prevent the electrolyte solution detection unit 212 and the power source from being directly connected, thereby preventing a short circuit between the voltage Vs and the ground terminal, and it is possible to protect the battery module 110, the electrolyte solution leakage detection sensor 210, and the battery monitoring circuit 220 by limiting current. Also, since the electrolyte solution detection unit 212 is designed so as to be regarded as an open circuit when there is no leakage of the electrolyte solution, it is possible to prevent leakage current from occurring. Further, since the RC filter circuits 213 and 214 are adopted such that whether the electrolyte solution has leaked is prevented from being erroneously detected due to transient AC noise. Accordingly, the detection accuracy can be improved.

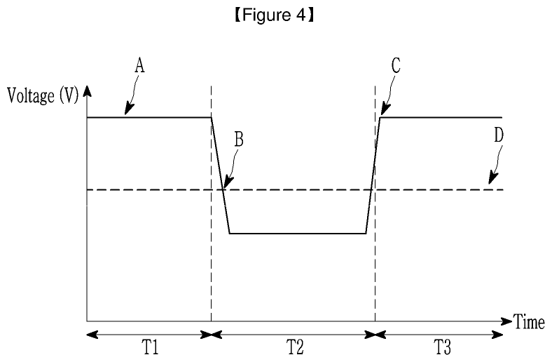

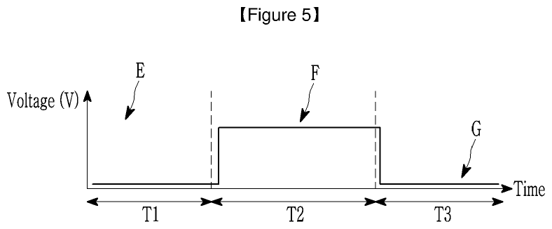

FIGS. 4 and 5 are drawings illustrating the operation of the electrolyte solution leakage detection device according to the exemplary embodiment.

Referring to FIGS. 4 and 5, a time period T1 may correspond to a normal state in which solution leakage has not occurred. In the time period T1, the first input voltage Via which is applied to the negative input terminal of the comparison circuit 215 may be 5 V (see reference symbol “A”). At this time, the output voltage Vo which is output from the output terminal of the comparison circuit 215 may be 0 V (see reference symbol “E”). Here, the second input voltage Vib which is applied to the positive input terminal of the comparison circuit 215 may be 2.5 V (see reference symbol “D”).

A time period T2 may correspond to a state in which solution leakage has occurred. As solution leakage occurs, the first input voltage Via which is applied to the negative input terminal of the comparison circuit 215 decreases to 2.5 V (see reference symbol “B”). Subsequently, the first input voltage Via may further decrease to a voltage lower than 2.5 V as the resistance value of the electrolyte solution decreases as described above. Accordingly, the output voltage Vo which is output from the output terminal of the comparison circuit 215 may be 5 V (see reference symbol “F”).

A time period T3 may correspond to a normal state after the leaked solution has been removed. In the time period T3, the first input voltage Via which is applied to the negative input terminal of the comparison circuit 215 may be 5 V (see reference symbol “C”). At this time, the output voltage Vo which is output from the output terminal of the comparison circuit 215 may be 0 V (see reference symbol “G”).

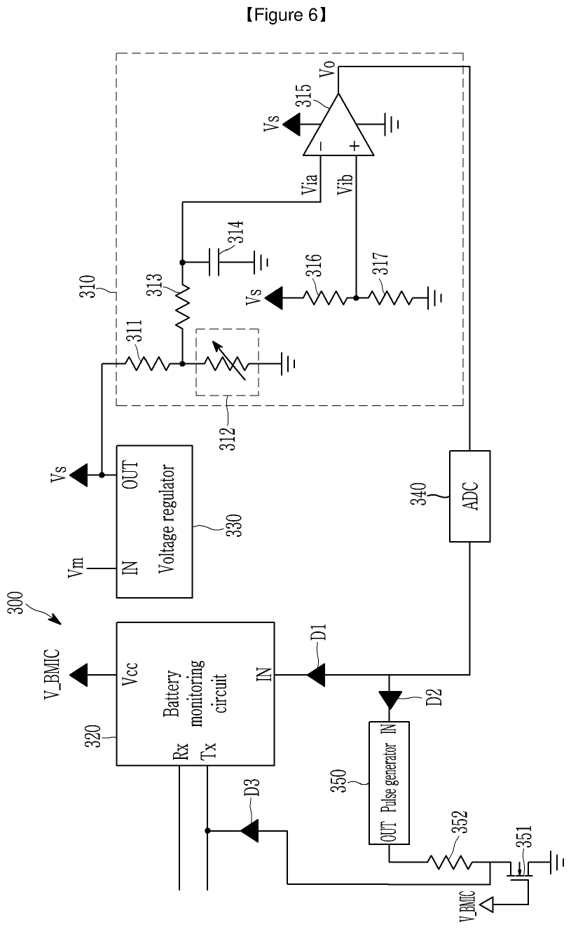

FIG. 6 is a drawing illustrating an electrolyte solution leakage detection device according to an exemplary embodiment.

Referring to FIG. 6, an electrolyte solution leakage detection device 300 may include an electrolyte solution leakage detection sensor 310 and a battery monitoring circuit 320. In the exemplary embodiment, the electrolyte solution leakage detection device 300 may correspond to the electrolyte solution leakage detection circuit 120 of FIG. 1.

The electrolyte solution leakage detection sensor 310 may include a resistor 311 and an electrolyte solution detection unit 312 which are connected in series between the power source for supplying the predetermined voltage Vs and a ground terminal, and the voltage of the contact point of the resistor 311 and the electrolyte solution detection unit 312 may be transmitted as a detection voltage to RC filter circuits 313 and 314. A detection voltage may pass through the RC filter circuits 313 and 314 and then be input as a first input voltage Via to a comparison circuit 315. Meanwhile, the electrolyte solution leakage detection sensor 310 may further include a plurality of resistors 316 and 317 which are connected in series between the power source for supplying the predetermined voltage Vs and the ground terminal. The voltage of the contact point of the plurality of resistors 316 and 317 may be input as a second input voltage Vib to the comparison circuit 315. In the exemplary embodiment, the electrolyte solution leakage detection device 300 may further include a voltage regulator 330 for generating a predetermined voltage Vs.

The battery monitoring circuit 320 may receive a signal corresponding to an output voltage Vo of the electrolyte solution leakage detection sensor 310. In the exemplary embodiment, the electrolyte solution leakage detection device 300 may further include an ADC 340 for converting the output voltage Vo of the electrolyte solution leakage detection sensor 310 into a digital signal which the battery monitoring circuit 320 can receive. In the exemplary embodiment, the electrolyte solution leakage detection device 300 may further include a diode D1 to block a current path in the opposite direction. In the exemplary embodiment, the battery monitoring circuit 320 may be set to one mode of an active mode in which it monitors a battery module (for example, reference symbol “110” in FIG. 1) and a shutdown mode in which it does not monitor the battery module 110. In the active mode, a predetermined voltage V_BMIC is supplied to a power terminal Vcc (for example, a power pin) of the battery monitoring circuit 320 to enable the battery monitoring circuit 320 to operate. In the shutdown mode, the predetermined voltage V_BMIC may be blocked so as not to be supplied to the power terminal Vcc of the battery monitoring circuit 320. Accordingly, the battery monitoring circuit 320 may not operate. In the exemplary embodiment, the predetermined voltage V_BMIC may be the same as the predetermined voltage Vs which is supplied to the electrolyte solution leakage detection sensor 310. In the exemplary embodiment, the electrolyte solution leakage detection device 300 may further include a pulse generator 350 such that it is possible to detect electrolyte solution leakage even when the battery monitoring circuit 320 is in the shutdown mode.

An output voltage Vo of the electrolyte solution leakage detection sensor 310 may be supplied to an input terminal IN of the pulse generator 350. In the exemplary embodiment, a signal obtained by converting the output voltage Vo of the electrolyte solution leakage detection sensor 310 by the ADC 340 may be input to the input terminal IN of the pulse generator 350. In the exemplary embodiment, the electrolyte solution leakage detection device 300 may further include a diode D2 to block a current path in the opposite direction (i.e., a current path from the input terminal IN of the pulse generator 350 to the electrolyte solution leakage detection sensor 310). The anode of the diode D2 may be connected to the output terminal of the electrolyte solution leakage detection sensor 310, and the cathode thereof may be connected to the input terminal IN of the pulse generator 350.

Between the output terminal OUT of the pulse generator 350 and a ground terminal, a transistor 351 may be connected. In other words, a first terminal of the transistor 351 may be connected to the output terminal OUT of the pulse generator 350, and a second terminal of the transistor 351 may be connected to the ground terminal. Also, a control terminal of the transistor 351 receives the same voltage as that of the power terminal Vcc of the battery monitoring circuit 320. For example, the control terminal of the transistor 351 may be connected to the power terminal Vcc of the battery monitoring circuit 320. Further, the first terminal of the transistor 351 may be connected to a transmission terminal Tx (for example, a transmission pin) of the battery monitoring circuit 320. In the exemplary embodiment, the first terminal of the transistor 351 may be connected to a communication line for transmission between the transmission terminal Tx of the battery monitoring circuit 320 and a battery management system (for example, reference symbol “10” in FIG. 1). In the exemplary embodiment, the electrolyte solution leakage detection device 300 may further include a diode D3 to block a current path in the opposite direction (i.e., a current path from the communication line for transmission to the first terminal of the transistor 351). The anode of the diode D3 may be connected to the first terminal of the transistor 351, and the cathode thereof may be connected to the transmission terminal Tx of the battery monitoring circuit 320. In the exemplary embodiment, between the output terminal OUT of the pulse generator 350 and the first terminal of the transistor 351, a resistor 352 may be connected.

The transistor 351 may be turned on when a predetermined voltage (for example, 5 V) is applied to the power terminal Vcc of the battery monitoring circuit 320, and may be turned off when the voltage is blocked so as not to be applied to the power terminal Vcc of the battery monitoring circuit 320. In the exemplary embodiment, the transistor 351 may be an n-channel transistor, for example, an n-channel metal oxide semiconductor field effect transistor (MOSFET). In this case, the first terminal, second terminal, and control terminal of the transistor 351 may be a drain, a source, and a gate, respectively.

In the active mode, the electrolyte solution leakage detection sensor 310 and the battery monitoring circuit 320 operate identically to the electrolyte solution leakage detection sensor 210 and the battery monitoring circuit 220 described with reference to FIG. 2, and thus a description thereof will not be made. Meanwhile, in the active mode, since the predetermined voltage is applied to the power terminal Vcc of the battery monitoring circuit 320, the transistor 351 is turned on. Accordingly, 0 V is applied to the anode of the diode D3, which may not affect communication through the transmission terminal Tx of the battery monitoring circuit 320.

In the shutdown mode, the voltage is blocked so as not to be applied to the power terminal Vcc of the battery monitoring circuit 320, such that the transistor 351 is turned off. Also, when the electrolyte solution leaks, since the output voltage Vo is output from the electrolyte solution leakage detection sensor 310, the pulse generator 350 may generate a pulse signal and output it to the output terminal OUT, in response to the output voltage Vo of the electrolyte solution leakage detection sensor 310. In other words, when the voltage input to the input terminal IN of the pulse generator 350 is higher than a threshold voltage, the pulse generator may generate a pulse signal and output it to the output terminal OUT. In this case, since the transistor 351 is off, the pulse signal of the pulse generator 350 may be applied to the transmission terminal Tx of the battery monitoring circuit 320. The battery monitoring circuit 320 may transition to the active mode in response to the pulse signal transmitted to the transmission terminal Tx. Then, the battery monitoring circuit 320 may transmit information corresponding to the output voltage Vo of the electrolyte solution leakage detection sensor 310 to the battery management system 10.

In the exemplary embodiment, the transistor 351, the resistor 352, and the diode D3 may transmit the pulse signal of the pulse generator 350 to the transmission terminal Tx of the battery monitoring circuit 320 in the shutdown mode, and operate as a transfer circuit which blocks transfer of the pulse signal, in the active mode.

According to the above-described exemplary embodiment, the battery monitoring circuit 320 may detect electrolyte solution leakage even in the shutdown mode.

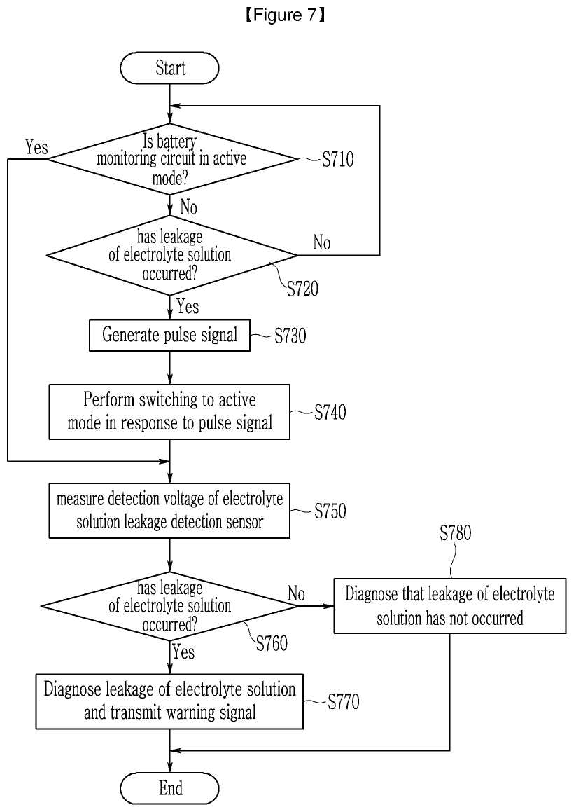

FIG. 7 is a flow chart illustrating an electrolyte solution leakage detection method of the battery device according to the exemplary embodiment.

Referring to FIG. 7, when a battery monitoring circuit for a battery pack is in an active mode (S710), the battery monitoring circuit measures a voltage corresponding to electrolyte solution leakage (S750). In I the exemplary embodiment, the battery monitoring circuit may measure a detection voltage which is output from an electrolyte solution leakage detection sensor (S750).

When the battery monitoring circuit for the battery pack is in a shutdown mode, if leakage of the electrolyte solution occurs in the battery pack (S720), the battery device generates a pulse signal in response to the leakage of the electrolyte solution (S730). In response to the pulse signal, the battery monitoring circuit transitions to the active mode (S740), and measures the voltage corresponding to the leakage of the electrolyte solution (S750). In the exemplary embodiment, in response to an output voltage of a comparison circuit output from the electrolyte solution leakage detection sensor in response to the leakage of the electrolyte solution, a pulse generator may generate a pulse signal, and the battery monitoring circuit may transition to the active mode in response to the pulse signal of the pulse generator.

When the voltage measured by the battery monitoring circuit is higher than a reference voltage (S760), the battery device may diagnose the leakage of the electrolyte solution, and transmit a warning signal to an external device (for example, a vehicle) (S770). When the measured voltage is not higher than the reference voltage, the battery device may diagnose that leakage of the electrolyte solution has not occurred (S780).

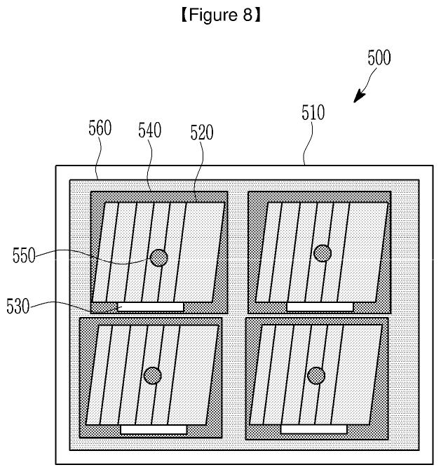

Now, a battery pack to which electrolyte solution leakage detection methods according to various exemplary embodiments may be applied will be described with reference to FIG. 8.

FIG. 8 is a drawing illustrating an example of the structure of a battery pack according to an exemplary embodiment.

Referring to FIG. 8, a battery pack 500 may be formed by combining a lower case 510 and an upper case (not shown in the drawing), and includes battery modules 520 provided therein. In FIG. 8, it is shown for ease of explanation that the battery pack 500 includes four battery modules 520; however, the number of battery modules 520 is not limited thereto. The battery modules 520 are connected to battery monitoring circuits 530, respectively. Each battery monitoring circuit 530 may monitor the battery cell voltages, temperature, and the like of a corresponding battery module 520.

Below each battery module 520, a lower cover 540 may be formed. Each lower cover 540 may have a shape capable of collecting an electrolyte solution which leaks in a corresponding battery module 520. To each lower cover 540, an electrolyte solution leakage detection sensor 550 may be attached. Each electrolyte solution leakage detection sensor 550 may sense the electrolyte solution collected in the lower cover 540, and output a corresponding voltage.

In the exemplary embodiment, on the lower case 510, a battery pack inner cover 560 may be formed. The battery pack inner cover 560 may be formed between the lower case 510 and the lower covers 540. The battery pack inner cover 560 may be formed of a non-conductive material to block a current path to the lower case 510 which may be formed by the leaked electrolyte solution.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

1. A battery pack comprising:
a battery module that includes a plurality of battery cells;
a battery monitoring circuit connected to the battery module and configured to monitors the battery module; and
an electrolyte solution leakage detection sensor configured to detect an electrolyte solution leakage in the battery module,
wherein the electrolyte solution leakage detection sensor includes the following:
a first resistor and an electrolyte solution detection circuit that are connected in series between a power source for supplying a first voltage and a ground terminal;
a second resistor and a third resistor that are connected in series between the power source and the ground terminal; and
a comparison circuit configured to receive a detection voltage of a contact point of the first resistor and the electrolyte solution detection circuit as a first input voltage, and receives a voltage of a contact point of the second resistor and the third resistor as a second input voltage, and transmit an output voltage to an input terminal of the battery monitoring circuit.

2. The battery pack of claim 1, wherein:
the comparison circuit is configured to:
output a high-level voltage signal when the first when the first input voltage is smaller than the second input voltage and output a low-level voltage signal when the first input voltage is larger than the second input voltage.

3. The battery pack of claim 2, wherein the electrolyte solution leakage detection sensor is configured to diagnose the electrolyte solution leakage
when the output voltage is higher than a reference voltage.

4. The battery pack of claim 1, wherein:
the electrolyte solution detection circuit includes a first detection node and a second detection node, and when the first detection node and the second detection node are electrically connected, the electrolyte solution leakage detection sensor is configured to diagnose the electrolyte solution leakage.

5. The battery pack of claim 1, further comprising:
an RC filter circuit configured to receive the detection voltage of the contact point of the first resistor and the electrolyte solution detection circuit and transfer the detection voltage to the comparison circuit.

6. The battery pack of claim 1, further comprising:
a voltage regulator configured to generate the first voltage from a voltage of the battery module.

7. The battery pack of claim 1, further comprising:
a lower case of the battery pack; and
a lower cover formed on the lower case and below the battery module, configured to collects the electrolyte solution leakage in the battery module, wherein the electrolyte solution leakage detection sensor is attached to the lower cover.

8. The battery pack of claim 1, wherein:
the battery monitoring circuit is configured to monitors the battery module in an active mode of the battery monitoring circuit.

9. The battery pack of claim 8, further comprising:
a pulse generator configured to generate a pulse signal for switching the battery monitoring circuit to the active mode and outputs the pulse signal to an output terminal, when the output voltage is higher than a threshold voltage; and
a transfer circuit configured to transfer the pulse signal to a transmission terminal of the battery monitoring circuit in a shutdown mode, and block a transfer of the pulse signal to the transmission terminal of the battery monitoring circuit in the active mode.

10. A battery device comprising:
a battery module that includes a plurality of battery cells;
a battery monitoring circuit connected to the battery module and configured to monitors the battery module;
an electrolyte solution leakage detection sensor configured to detect an electrolyte solution leakage in the battery module; and
a battery management system configured to manage the battery monitoring circuit and diagnoses the electrolyte solution leakage based on information received from the battery monitoring circuit,
wherein the electrolyte solution leakage detection sensor includes an electrolyte solution detection circuit whose resistance value varies in response to the electrolyte solution leakage in the battery module, and the electrolyte solution leakage detection sensor is configured to transmit an output voltage of a comparison circuit, which is determined based on a resistance value of the electrolyte solution detection unit, to an input terminal of the battery monitoring circuit.

11. The battery device of claim 10, wherein:
the battery management system is configured to diagnose the electrolyte solution leakage in the battery module in response to the output voltage being higher than a reference voltage based on information transmitted from the battery monitoring circuit.

12. The battery device of claim 10, wherein:
the electrolyte solution leakage detection sensor includes the following:
a first resistor and the electrolyte solution detection circuit that are connected in series between a power source for supplying a first voltage and a ground terminal;
a second resistor and a third resistor connected in series between the power source and the ground terminal; and
a comparison circuit configured to receive a detection voltage of the contact point of the first resistor and the electrolyte solution detection circuit as a first input voltage, and receives a voltage of the contact point of the second resistor and the third resistor as a second input voltage, and transmits an output voltage to an input terminal of the battery monitoring circuit.

13. The battery device of claim 12, further comprising:
a pulse generator configured to transmit a pulse signal to a transmission terminal of the battery monitoring circuit when the electrolyte solution leakage detection sensor detects the electrolyte solution leakage in the battery module in a shutdown mode of the battery monitoring circuit,
wherein the battery monitoring circuit is configured to transitions the battery module to an active mode in response to the pulse signal.

14. The battery device of claim 13, wherein:
the pulse generator is configured to generates the pulse signal in response to the output voltage being higher than a threshold voltage.

15. The battery device of claim 13, further comprising:
a transistor connected between an output terminal of the pulse generator and a ground terminal, and controls a transfer of the pulse signal to a transmission terminal of the battery monitoring circuit in based on a voltage supplied to a power terminal of the battery monitoring circuit.

16. The battery device of claim 15, wherein:
the battery module is in the active mode, in response to a second voltage being supplied to the power terminal of the battery monitoring circuit, and the battery module is in the shutdown mode in response to the second voltage being blocked so as not to be supplied to the power terminal of the battery monitoring circuit, and
the transistor is turned on to block a transfer of the pulse signal in response to the second voltage in the active mode, and is turned off to transfer the pulse signal in response to the blocking of the second voltage in the shutdown mode.

17. The battery device of claim 10, further comprising:
a lower cover formed below the battery module configured to collect the electrolyte solution leakage in the battery module, and has the electrolyte solution leakage detection sensor attached thereto.

18. An electrolyte solution leakage detection method of a battery device which includes a battery module, a battery monitoring circuit for monitoring the battery module, and an electrolyte solution leakage detection sensor, the method comprising:
generating a pulse signal when an electrolyte solution leaks in the battery module in a state where the battery monitoring circuit is in a shutdown mode;
switching the battery monitoring circuit to an active mode in response to the pulse signal;
allowing the electrolyte solution leakage detection sensor to measure an output voltage based on a resistance value which varies in response to the electrolyte solution leakage; and
commanding the battery monitoring circuit, in the active mode, to diagnose the electrolyte solution leakage in response t the output voltage being higher than a reference voltage.

19. The electrolyte solution leakage detection method of claim 18, further comprising:
receiving a detection voltage of the contact point of a first resistor and an electrolyte solution detection circuit as a first input voltage;
receiving a voltage of the contact point of a second resistor and a third resistor as a second input voltage;
comparing the first input voltage and the second input voltage; and, outputting a high-level voltage signal when the first input voltage is smaller than the second input voltage, and outputting a low-level voltage signal when the first input voltage is larger than the second input voltage.
